(19) United States
(12) Patent Application Publication
(10) Pub. No.: US 2012/0067284 A1
(43) Pub. Date: Mar. 22, 2012

(54) APPARATUS

(75) Inventors: Pekka Soininen, Helsinki (FI); Jarmo Skarp, Espoo (FI)

(73) Assignee: BENEQ OY, Vantaa (FI)

(21) Appl. No.: 13/320,982

(22) PCT Filed: Jun. 14, 2010
(86) PCT No.: PCT/FI10/50492

§ 371 Date: Nov. 17, 2011

(30) Foreign Application Priority Data
Jun. 15, 2009 (FI) 20095676

(51) Int. Cl. C23C 16/44; B25J 15/00

(52) U.S. Cl. 118/719; 901/30

(57) ABSTRACT

An apparatus for carrying out atomic layer deposition onto a surface of a substrate by exposing the surface of the substrate to alternate starting material surface reactions, the apparatus including two or more low-pressure chambers, two or more separate reaction chambers arranged to be placed inside the low-pressure chambers, and at least one starting material feed system common to two or more low-pressure chambers for carrying out atomic layer deposition. The apparatus includes at least one loading device arranged to load and unload substrates to/from the reaction chamber and further to load and unload the reaction chambers to/from the low-pressure chambers.

The present invention relates to an atomic layer deposition apparatus, and particularly to an apparatus according to the preamble of claim 1 for carrying out atomic layer deposition onto a surface of a substrate by exposing the surface of the substrate to alternate starting material surface reactions, the apparatus comprising two or more low-pressure chambers, two or more separate movable reaction chambers arranged to be placed inside the low-pressure chambers, and at least one starting material feed system common to two or more low pressure chambers for carrying out atomic layer deposition.

In prior art atomic layer deposition apparatuses, the substrates to be processed are exposed to alternate saturated surface reactions of starting materials by feeding alternately two or more gaseous starting materials to a coating chamber in order to coat a substrate or dope a porous substrate. Between starting material feeds, the coating chamber may be flushed by a flushing gas. In accordance with the prior art, such an atomic layer deposition apparatus may comprise a gas feed system for feeding starting materials and flushing gases to the coating chamber, heating means for heating substrates loaded into the coating chamber to a process temperature, loading means for loading and unloading substrates to/from the coating chamber, and a control unit for controlling the gas feeds and the heating as well as the substrate loading and unloading to/from the apparatus. The apparatus may also comprise several low-pressure chambers that may simultaneously or non-simultaneously be used for processing many different substrates in different reaction chambers. From among these many low-pressure chambers, two or more may be connected to a common starting material feed system.

When the apparatus comprises several coating chambers that are operationally connected to a common starting material feed system and control system, substrates may be loaded to several coating chambers, and these substrates in the different coating chambers may be treated with gaseous starting materials simultaneously, alternately, or consecutively. This enables the atomic layer deposition apparatus to be made to operate substantially continuously such that substrates are processed according to an atomic layer deposition method at one time in one coating chamber. This makes it possible to process the substrates substantially continuously, when substrates in one or more coating chambers are processed at one time and substrates in other coating chambers are loaded to a coating chamber or unloaded therefrom. This provides a more uniform supply of processed substrates from the apparatus, which further facilitates logistic challenges and decreases the need for intermediate storage, for instance.

In such prior art apparatuses comprising several parallel coating chambers, a problem has arisen regarding the complex substrate loading devices.

### BRIEF DESCRIPTION OF THE INVENTION

An object of the invention is thus to provide an apparatus for carrying out atomic layer deposition onto a surface of a substrate so as to enable the aforementioned problems to be solved. The object of the invention is achieved by an apparatus according to the characterizing part of claim 1.

Preferred embodiments of the invention are disclosed in the dependent claims.

An idea underlying the invention is that an atomic layer deposition apparatus is provided with two or more coating chambers that are operationally connected to a starting material feed system and a control system of the apparatus. In such a case, substrates to be processed may be loaded to several coating chambers, and these substrates in the different coating chambers may be heated and treated with gaseous starting materials simultaneously, alternately, or consecutively. According to an embodiment, the substrates may be heated e.g. in three coating chambers while at the same time substrates in one coating chamber are processed by an atomic layer deposition method by exposing the surface of a substrate to alternate surface reactions of the gaseous starting materials. When the substrate processing in said one coating chamber is complete and has ended, the processed substrates are removed therefrom and replaced by new substrates, and the process starts heating them. Simultaneously, the process starts processing, according to the atomic layer deposition method, the heated substrates in a second coating chamber. Similarly, after the processing in the second coating chamber has ended, the process moves to process substrates in a third coating chamber that have already been heated, and new substrates that are about to be heated are loaded into the second coating chamber, etc.

An advantage of the method and system according to the invention is that the several coating chambers enable the atomic layer deposition apparatus to operate substantially continuously such that substrates are processed according to the atomic layer deposition method at one time in one coating chamber. This enables the substrates to be processed substantially continuously, when substrates in one coating chamber are processed at one time while substrates in other coating chambers are simultaneously already being heated so as to be ready for processing. This provides a more uniform supply of processed substrates from the apparatus, which further facilitates logistic challenges and decreases the need for intermediate storage, for instance. At the same time, the number of peripherals for the apparatus may be lowered when one starting material feed system and substrate loading system may serve a plurality of coating chambers. Furthermore, the coating chambers of one apparatus may be arranged on top of one another, for instance, which enables the surface area of the apparatus to be decreased, which further saves the floor area in a production space. The solution according to the invention also enables smaller coating chambers to be used for the same substrate processing volume. In smaller coating chambers, uniformity of gas feed can be produced in a better way, which improves substrate processing quality.

### BRIEF DESCRIPTION OF THE FIGURES

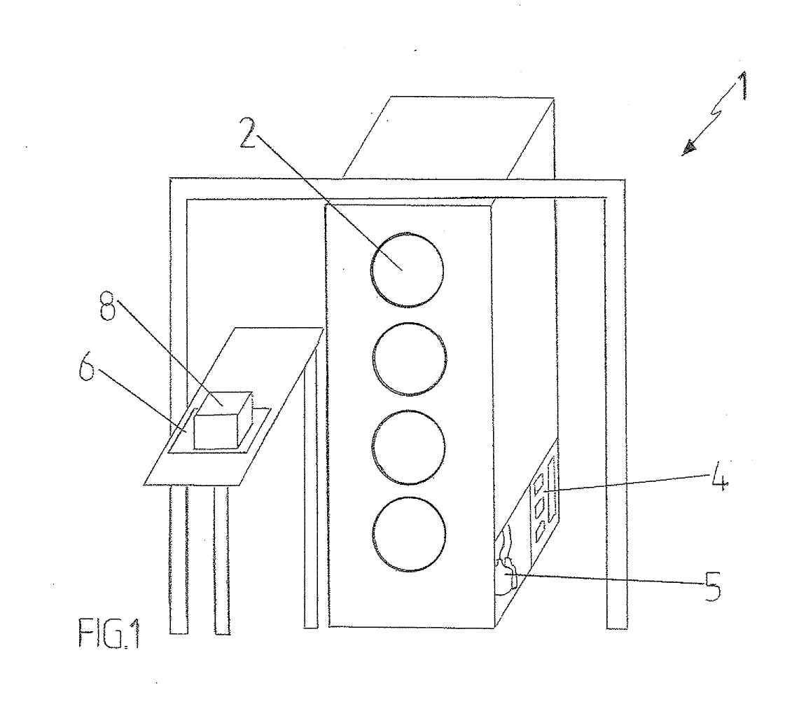

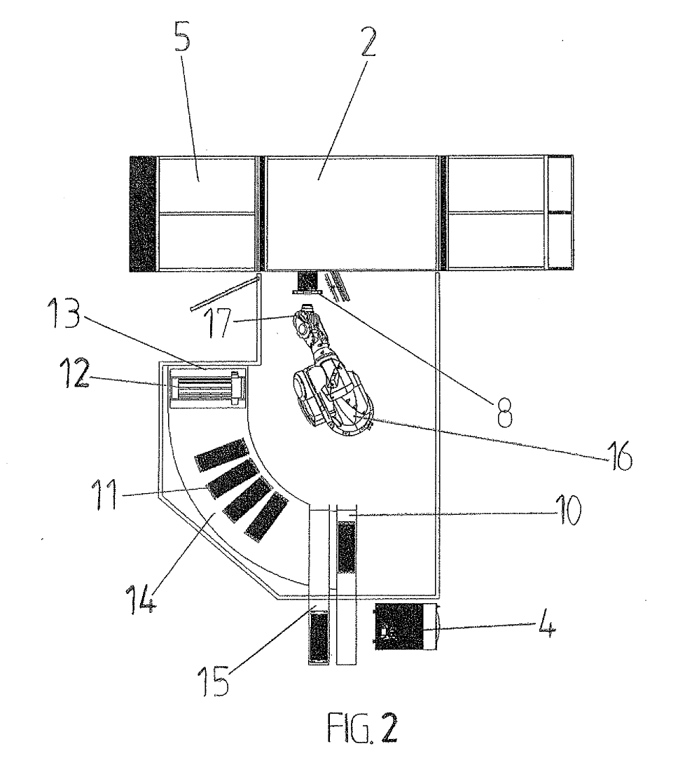

The invention is now described in closer detail in connection with preferred embodiments and with reference to the accompanying FIGS. 1 and 2, which are schematic views showing some embodiments of the present invention.

### DETAILED DESCRIPTION OF THE INVENTION

FIG. 1 shows an embodiment of an apparatus 1 according to the present invention for carrying out atomic layer deposition. The apparatus comprises a body provided with four low-pressure chambers 2, a starting material feed system 5, and a control system 4. In other words, according to the present invention, one and the same atomic layer deposition apparatus is provided with several low-pressure chambers 2. The apparatus 1 may have two or more low-pressure chambers 2. In FIG. 1, the low-pressure chambers 2 are placed in the apparatus 1 on top of one another in a vertical direction but, alternatively, the low-pressure chambers 2 may be placed in the apparatus side by side in a horizontal direction. Further, if the apparatus comprises a large number of low-pressure chambers 2, they may be placed e.g. in a matrix wherein the low-pressure chambers 2 reside both side by side in the horizontal direction and on top of one another in the vertical direction. The low-pressure chambers 2 may have any shape or form, e.g. that of a circular cylinder, as in FIG. 1.

The apparatus 1 further comprises a starting material feed system 5 for feeding gaseous starting materials to the low-pressure chambers 2 so as to carry out atomic layer deposition. The starting material feed system 5 comprises one or more starting material sources, such as a gas container or a crucible, as well as pipes for leading the starting materials to the lowpressure chambers 2. In other words, the starting materials are fed to a reactor in a gaseous state, but in a starting material tank they may be as a gas, liquid, or solid. The starting material feed system 5 is at least partly common to two or more or all low-pressure chambers 2. For instance, at least some of gaseous starting material sources or flushing gas sources may be common to all low-pressure chambers 2 or, alternatively, each low-pressure chamber 2 may also have some starting material sources of its own. Suction means, which belong to the starting material feed system 5, for removing starting materials or flushing gases from the low-pressure chambers 2, may also be common to two or more or all low-pressure chambers 2. In a particular case, the apparatus 1 may be provided with two or more starting material feed systems 5 such that one starting material feed system 5 is at least partly common to at least two low-pressure chambers 2. In other words, the point is that at least a part of the starting material feed system 5, including all elements associated with feeding and removing starting materials, is common to at least two coating chambers 2 to which it is operationally connected.

The apparatus 1 preferably comprises low-pressure means for generating a low pressure in the low-pressure chambers 2. The lowpressure means are preferably common to all or to at least two low-pressure chambers 2 or, alternatively, each low-pressure chamber 2 may comprise low-pressure means of its own. The apparatus 1 also comprises separate reaction chambers 8 inside which substrates are placed. The reaction chambers 8, in turn, are placed inside the low-pressure chambers 2 such that atomic layer deposition onto the surface of the substrates is carried out inside the reaction chambers 8. In such a case, the reaction chambers 8 constitute the coating chambers of the present invention. In the solution according to FIG. 1, the reaction chambers 8 are movable such that they may be loaded into the low-pressure chamber 2 and removed therefrom. The substrates are further placed inside the reaction chambers 8 and removed therefrom when the reaction chambers 8 are outside the low-pressure chambers 2. Then, the processing of the substrates by the atomic layer deposition method is carried out at one time in a reaction chamber 8 which resides inside one low-pressure chamber 2 while at the same time substrates in reaction chambers 8 residing inside other low-pressure chambers 2 are being heated. The reaction chambers 8 may also be provided fixedly inside the low-pressure chambers 2 such that the substrates are loaded directly into the reaction chambers 8 inside the low-pressure chambers 2 for carrying out atomic layer deposition. The reaction chambers 8 may be made to receive one or more substrates simultaneously. The substrates may further be loaded onto a separate loading carrier which, in turn, is inserted into the reaction chamber 8. The loading carrier may be made to receive one or more substrates. The loading carrier may be further loaded into a fixed reaction chamber 2 provided inside the low-pressure chamber 2 or, alternatively, the loading carrier may be loaded into a movable reaction chamber 8 outside the low-pressure chamber 2. The loading carrier may be further provided with a gas distribution part for distributing gaseous starting materials evenly inside the reaction chamber and in the loading carrier.

In an alternative embodiment of the present invention, the apparatus 1 comprises only one low-pressure chamber 2 but a plurality of reaction chambers 8, which thus constitute coating chambers according to the invention, inside which substrates are processed by an atomic layer deposition method. In such a case, the low-pressure chamber 2 may be arranged to receive two or more reaction chambers at the same time. The processing of the substrates by the atomic layer deposition method is carried out in one reaction chamber 8 inside the low-pressure chamber 2 at one time while at the same time other substrates inside the reaction chambers inside the low-pressure chamber 2 are being heated. When the processing of the substrates in one reaction chamber 8 is completed, the low-pressure chamber may be opened and the processed substrates may be removed from the low-pressure chamber 2 and the particular reaction chamber 8 and new substrates may be loaded to replace the previous ones. Next, the low-pressure chamber 2 is closed, and the process starts processing the already-heated substrates inside the next reaction chamber 8, and at the same time the process starts to heat the new, loaded substrates. Also in this embodiment, the reaction chambers 8 may be fixedly installed inside the low-pressure chamber 2, in which case the substrates may be loaded directly inside the reaction chambers 8 inside the low-pressure chamber 2.

In still another embodiment, the apparatus may comprise one or more low-pressure chambers 2, two or more reaction chambers 8 that serve as coating chambers, and one or more heating chambers, such as a heating furnace or a heating station. According to this embodiment, substrates in a reaction chamber 8 installed in one low-pressure chamber 2 may be processed at one time while at the same time substrates in other reaction chambers 8 in the heating chamber are being heated. Alternatively, the reaction chambers are installed fixedly. After the processing of the substrates of this one reaction chamber 8, the processed substrates, together with the reaction chamber 8, are removed from the particular low-pressure chamber 2, and a new reaction chamber 8 containing heated substrates is loaded from the heating chamber to this low-pressure chamber 2. If the apparatus comprises two or more low-pressure chambers 2, substrates inside one low-pressure chamber 2 may be processed at the same time while processed substrates are being removed from inside another low-pressure chamber 2 and while new substrates are being loaded. Thus, the time-consuming procedures of heating and loading and removing substrates causes no dead time in the operation of the apparatus but it may process the substrates substantially continuously. In all previous embodiments, wherein reaction chambers 8 are or will be placed inside a low-pressure chamber 2, each low-pressure chamber 2 may simultaneously be provided with two or more reaction chambers 8.

According to FIG. 1, the apparatus further comprises a loading device 6 for loading substrates to the low-pressure chambers 2. The loading device 6 is preferably made to serve two or more low-pressure chambers 2, preferably all low-pressure chambers 2 of the apparatus 1. The loading device 6 is thus arranged to load and unload substrates to/from one or more low-pressure chambers 2. The loading device 6 is further arranged to load and unload separate movable reaction chambers 8 to/from one or more low-pressure chambers 2. In such a case, the loading device 6 may further be made to load and unload substrates to/from the movable reaction chambers 8. FIG. 1 shows a schematic view of the loading device 6, wherein substrates are loaded to the reaction chamber 8 at a substrate loading station. Next, the reaction chamber 8 is loaded to the low-pressure chamber 2 by using the loading device 6 for atomic layer deposition. After the processing carried out in the low-pressure chamber 2, the reaction chamber 8 is removed from the low-pressure chamber 2 and transferred to the substrate loading station at which the processed substrates are removed from the reaction chamber 8 and further forwarded, loaded on transport carriers, for instance. Accordingly, the same loading device 6 may be used for serving all low-pressure chambers and/or reaction chambers of the apparatus 1. Alternatively, the loading device 6 may also be arranged to serve two or more adjacent apparatuses 1.

The low-pressure chambers 2 may be provided such that they comprise a loading hatch through which substrates or reaction chambers 8 are loadable into the low-pressure chamber 2 and removable therefrom by the loading device 6. In an alternative embodiment, the low-pressure chamber 2 separately comprises a loading hatch for loading the reaction chamber 8 and/or substrates to the coating chamber 2 as well as an unloading hatch for removing the reaction chamber 8 and/or substrates from the low-pressure chamber 2. In such a case, the loading device 6 may comprise separate actuators for loading and unloading the low-pressure chamber 2. Preferably, the loading hatch and the unloading hatch are provided on opposite sides of the low-pressure chamber 2 such that the substrates or the reaction chamber 8 may pass through the low-pressure chamber 2.

The apparatus 1 is further provided with heating means for enabling substrates loaded into the low-pressure chamber 2 to be heated to a desired temperature. In order to carry out atomic layer deposition, the substrates are usually to be heated to a temperature that is clearly above the temperature of the surroundings before the atomic layer deposition may be carried out efficiently. The heating has to be carried out in a controlled manner, so it usually takes a lot of time in relation to the actual atomic layer deposition procedure, particularly when depositing thinsheets onto substrates. Preferably, the heating means are provided for heating substrates loaded into each coating chamber 2 independently of other coating chambers 2. In other words, the heating means and the gas feed system 5 are preferably provided such that the operation of each coating chamber 2 is independent of other coating chambers, which makes it possible to heat substrates in one or more coating chambers 2 at the same time when in one or more other coating chambers atomic layer deposition is carried out utilizing the starting material feed system 5. Each coating chamber 2 may have separate heating means or, alternatively, the heating means may be at least partly common to two or more coating chambers 2.

The apparatus 1 according to the present invention further comprises a control system 4 for controlling the operation of the coating chambers 2 and/or the starting material feed system 5 and/or the loading device 6 and/or the heating means. The control system 4 enables the operation of the apparatus to be controlled as desired such that the processing of the substrates may be entirely carried out by the apparatus 1 as desired. In such a case, the control system 4 may be e.g. arranged to simultaneously use the heating means for heating the substrates in one or more coating chambers 2 and the starting material feed means 5 for carrying out the coating process simultaneously in one or more other coating chambers 2. Then, the operation of the apparatus may be implemented e.g. such that each coating chamber 2 operates at a slightly different stage, so that when substrates are being processed in one coating chamber 2, other coating chambers 2 are for processing of the substrates to be carried out at different stages of heating the substrates. Alternatively, the starting material feed system 5 may be arranged to feed starting materials simultaneously to one or more coating chambers 2. Thus, the starting material feed system 5 may further be arranged to feed the same or different starting materials to two or more coating chambers 2 simultaneously or non-simultaneously. Hence, the starting material feed system 5 and the loading device as well may be used efficiently with no long pauses of inactivity.

FIG. 2 shows an embodiment of the present invention wherein the apparatus 1 for carrying out atomic layer deposition comprises two or more low-pressure chambers 2 residing parallelly and/or on top of one another. The low-pressure chambers 2 are equipped with fixed reaction chambers 8 provided therein, the reaction chambers 8 being operationally connected to the starting material feed system 5. The loading device comprises a loading station 10 wherefrom new substrates 11 are received. The substrates 11 may further be already installed on a support (not shown) which is further installed onto a loading carrier 12. Alternatively, the substrates 11 are loaded directly to the loading carrier 12. The loading device comprises a pre-heating station 13, where the substrates 11 are heated before they are loaded into the reaction chamber 8 inside the low-pressure chamber 2 for processing. The pre-heating station 13 may comprise a furnace or a corresponding heating chamber to receive the substrates 11 or the loading carrier 12 together with its substrates 11 for heating before they are loaded into the reaction chamber 8 and the low-pressure chamber 2. In the pre-heating station 13, the substrates 11 are preferably heated to a processing temperature. The loading carrier 12 is preferably provided such that it forms a part of the reaction chamber 8, in which case placing the loading carrier 12 inside the reaction chamber 8 simultaneously closes the reaction chamber 8. The loading carrier 12 is preferably further provided with a gas distribution part (not shown) before it is loaded into the low-pressure chamber 2. Similarly, the gas distribution part, such as a gas distribution plate, is removed from the loading carrier 12 when it is removed from the low-pressure chamber 2. The gas distribution part is installed on top of the substrates 11 such that it distributes the gaseous starting materials evenly onto the substrates 11.

The substrates 11 heated in the pre-heating station 13 are loaded into the reaction chamber 8 on the loading carrier 12 and the low-pressure chamber 2 is closed for processing. At the same time, the next substrates 11 are loaded onto a new loading carrier 12, which is placed in the preheating station 13 for heating the substrates 11. After processing, the low-pressure chamber 2 is opened and the reaction chamber 8 is opened and the loading carrier 12 is removed from inside the reaction chamber 8 and placed onto the loading station 10. In the loading station 10, the substrates 11 or the support together with the substrates 11 are removed from the loading carrier 12 and transferred to a cooling station 14, where the processed substrates 11 are left to cool. Once the processed substrates 11 have cooled down, they are transferred from the cooling station 14 to a transport station 15 to be forwarded.

In the solution according to FIG. 2, all previous procedures are executed by one robot 16, which comprises one or more robot hands 17. The loading device is preferably placed outside the low-pressure chamber 2, under atmospheric air pressure, i.e. normal air pressure. The point in the loading device according to the invention is that the same loading device is capable of loading substrates 11 to a separate movable reaction chamber 8 or to a movable part of the reaction chamber, such as the loading carrier 12, and further of loading the reaction chamber 8 or a part thereof into the low-pressure chamber. Similarly, the loading device is capable of removing the reaction chamber 8 or a part 12 thereof from the low-pressure chamber, and further the substrates 11 from the reaction chamber 8 and the part 12 thereof.

It is to be noted that in the present application, a movable reaction chamber refers to the entire reaction chamber or a part of a reaction chamber in which substrates are placed, i.e. for instance the loading carrier 12, which forms a part of the entire reaction chamber.

It is apparent to one skilled in the art that as technology advances, the basic idea of the invention may be implemented in many different ways. The invention and its embodiments are thus not restricted to the above-described examples but may vary within the scope of the claims.

1. An apparatus for carrying out atomic layer deposition onto a surface of a substrate by exposing the surface of the substrate to alternate starting material surface reactions, the apparatus comprising two or more low-pressure chambers, two or more separate movable reaction chambers arranged to be placed inside the low-pressure chambers, at least one starting material feed system common to two or more low-pressure chambers, and least one loading device arranged to load and unload substrates to/from the movable reaction chamber and further to load and unload the movable reaction chambers to/from the low-pressure chambers.

2. An apparatus as claimed in claim 1, wherein the loading device is placed outside the low-pressure chamber, in atmospheric air pressure.

3. An apparatus as claimed in claim 1, wherein the loading device is arranged to serve two or more low-pressure chambers.

4. An apparatus as claimed in claim 1, wherein the loading device comprises a robot provided with one or more robot hands for moving the substrates and the movable reaction chambers.

5. An apparatus as claimed in claim 1, whrein the loading device comprises a pre-heating station for heating the substrates before loading them into the low-pressure chamber.

6. An apparatus as claimed in claim 1, wherein the loading device comprises a cooling station for cooling the substrates processed in the low-pressure chamber.

7. An apparatus as claimed in claim 1, wherein the loading device further comprises a loading carrier onto which the substrates are placed to be processed in the low-pressure chamber.

8. An apparatus as claimed in claim 7, wherein the installation carrier forms a movable reaction chamber.

9. An apparatus as claimed in claim 8, wherein the installation carrier forms a part of the entire reaction chamber.

10. An apparatus as claimed in claim 7, wherein the installation carrier comprises a separate gas distribution part to be mounted on top of the substrates.

11. An apparatus as claimed in claim 1, wherein in the apparatus, the low-pressure chambers are placed parallelly, on top of one another, or in a matrix.

12. An apparatus as claimed in claim 1, wherein the low-pressure chamber is arranged to receive one or more movable reaction chambers.

13. An apparatus as claimed in claim 1, wherein the movable reaction chamber is arranged to receive one or more substrates.

14. An apparatus as claimed in claim 1, wherein the apparatus comprises heating means for heating substrates loaded into each low-pressure chamber independently of other low-pressure chambers.

15. An apparatus as claimed in claim 14, wherein each low-pressure chamber comprises separate heating means.

16. An apparatus as claimed in claim 1, wherein the starting material feed system is arranged to feed starting materials simultaneously to one or more low-pressure chambers.

17. An apparatus as claimed in claim 16, wherein the starting material feed system is arranged to feed the same starting materials or different starting materials to two or more low-pressure chambers simultaneously or non-simultaneously.

18. An apparatus as claimed in claim 1, apparatus further comprising a control system for controlling the operation of the low-pressure chambers and/or the reaction chambers and/or the starting material feed system and/or the loading device and/or the heating means and/or the heating chamber.

19. An apparatus as claimed in claim 1, wherein the low-pressure chambers comprise a loading hatch for loading the movable reaction chamber to the low-pressure chamber as well as an unloading hatch for removing the movable reaction chamber from the low-pressure chamber.

20. An apparatus as claimed in claim 19, wherein the loading hatch and the unloading hatch are provided on opposite sides of the low-pressure chamber.
